(19) United States
(12) Patent Application Publication
(10) Pub. No.: US 2016/0062227 A1
(43) Pub. Date: Mar. 3, 2016

(54) Mask monitor mark and method for marking the mark

(71) Applicant: MACRONIX INTERNATIONAL CO., LTD., Hsinchu (TW)

(72) Inventor: Chin-Cheng Yang, Kaohsiung County (TW)

(21) Appl. No.: 14/475,781

(22) Filed: Sep. 3, 2014

(51) Int. Cl. G03F 1/42; G01B 21/00

(52) U.S. Cl. CPC G03F 1/42; G01B 21/00

(57) ABSTRACT

A method of monitoring mask uniformity includes selecting a unit monitor mark pattern and monitor mark locations based on a main cell size, determining a unit monitor mark sampling location and measurement methodology, and starting a mask making process. The mask critical dimension uniformity (CDU) is measured and data is analyzed. A process impact factor is identified if the mask CDU is not within a predetermined specification, and a mask making process parameter is adjusted based on the identified process impact factor. The mask making process, measuring, identifying and adjusting steps are repeated until the mask CDU is within the predetermined specification.

### TECHNICAL FIELD

The present disclosure relates generally to a photomask, and a method of fabricating semiconductor devices and masks. More particularly, the present disclosure relates to a process monitor mark on a photomask to improve critical dimension uniformity in the process of semiconductor device fabrication.

### BACKGROUND

In the semiconductor field, semiconductor manufacturers generally compete to bring to market semiconductor devices, such as memory devices, having both greater storage capacity and smaller physical size. Semiconductor device manufacturers attempt to achieve one or more of these goals by making the patterns formed on photoresist masks, photoresist layers, and corresponding fabricated semiconductor structures and devices dimensionally smaller. Alternatively or in addition, the manufacturers may attempt to place patterns on the mask, the photoresist layers, and corresponding fabricated semiconductor structures and devices dimensionally closer to one another so as to increase the density of patterns formed on the resultant semiconductor device.

Semiconductor devices are generally fabricated by performing a photolithography process in which a mask is subjected to light exposure to form a series of patterns on a photoresist layer. The patterns formed on the photoresist layer, along with one or more underlying layers between the photoresist layer and its corresponding substrate, are then etched to form patterns. These patterns can be visualized as elongated trenches surrounded or isolated by insulative walls (such as oxide layers). Thereafter, one or more conductive layers are formed in the etched patterns, forming electrical interconnects. Traditionally, the aforementioned one or more conductive layers were formed using conductive metals such as aluminum, or the like. More recently, conductive layers have been formed using a damascene process or a dual damascene process in which traditional metals such as aluminum are replaced with copper.

Semiconductor devices, such as memory devices, are fabricated by performing a photolithography process in which a mask is subjected to light exposure to form a series of patterns on a photoresist layer. The patterns formed on the photoresist layer, along with any underlying layers between the photoresist layer and its substrate, are then etched to form layers of the semiconductor device.

### BRIEF SUMMARY

In an exemplary embodiment, a method of monitoring mask uniformity includes selecting a unit monitor mark pattern and monitor mark locations based on a main cell size, determining a unit monitor mark sampling location and measurement methodology, and starting a mask making process. The mask critical dimension uniformity (CDU) is measured and data is analyzed. A process impact factor is identified if the mask CDU is not within a predetermined specification, and a mask making process parameter is adjusted based on the identified process impact factor. The mask making process, measuring, identifying and adjusting steps are repeated until the mask CDU is within the predetermined specification.

In another exemplary embodiment, a photomask includes a cell pattern and a plurality of monitor marks surrounding the cell pattern.

### BRIEF DESCRIPTION OF THE DRAWINGS

For a more complete understanding of the present disclosure, example embodiments, and their advantages, reference is now made to the following description taken in conjunction with the accompanying drawings, in which like reference numbers indicate like features, and:

FIG. 1 is a scanning electron microscope (SEM) picture of an edge region of a semiconductor device; (The right hand side is the enlarged image of a portion of the left hand side)

FIG. 2 is a top view of an exemplary photomask for use in fabricating a semiconductor device;

FIG. 3 is an enlarged top view of an exemplary monitor mark of the photomask of FIG. 2;

FIG. 4A-4C are top views of alternative monitor mark patterns according to various embodiments;

FIG. 5 is a flow chart illustrating an exemplary mask CDU monitoring process according to an embodiment;

FIG. 6 illustrates an exemplary unit monitor mark sampling and measurement result according to an embodiment;

FIGS. 7A-7F are cross-sectional views of an exemplary mask art different stages of a process flow of mask making according to an embodiment.

Although similar reference numbers may be used to refer to similar elements for convenience, it can be appreciated that each of the various example embodiments may be considered to be distinct variations.

### DETAILED DESCRIPTION

Example embodiments will now be described hereinafter with reference to the accompanying drawings, which form a part hereof, and which illustrate example embodiments which may be practiced. As used in the disclosures and the appended claims, the terms “example embodiment,” “exemplary embodiment,” and “present embodiment” do not necessarily refer to a single embodiment, although they may, and various example embodiments may be readily combined and/or interchanged without departing from the scope or spirit of example embodiments. Furthermore, the terminology as used herein is for the purpose of describing example embodiments only and is not intended to be limitations. In this respect, as used herein, the term “in” may include “in” and “on”, and the terms “a”, “an” and “the” may include singular and plural references. Furthermore, as used herein, the term “by” may also mean “from”, depending on the context. Furthermore, as used herein, the term “if” may also mean “when” or “upon”, depending on the context. Furthermore, as used herein, the words “and/or” may refer to and encompass any and all possible combinations of one or more of the associated listed items.

Despite recent advances in shrinking physical size of semiconductor features, it is recognized herein that conventional methods suffer from several problems, including, but not limited to, poor or low critical dimension uniformity (CDU), poor or low depth of focus (DoF), unreliability of proper and/or accurate pattern formation on the photoresist layer, and frequent occurrence of blind patterns (or holes).

Present example embodiments relate generally to improved semiconductor devices and masks, and improved methods of fabricating semiconductor devices and masks.

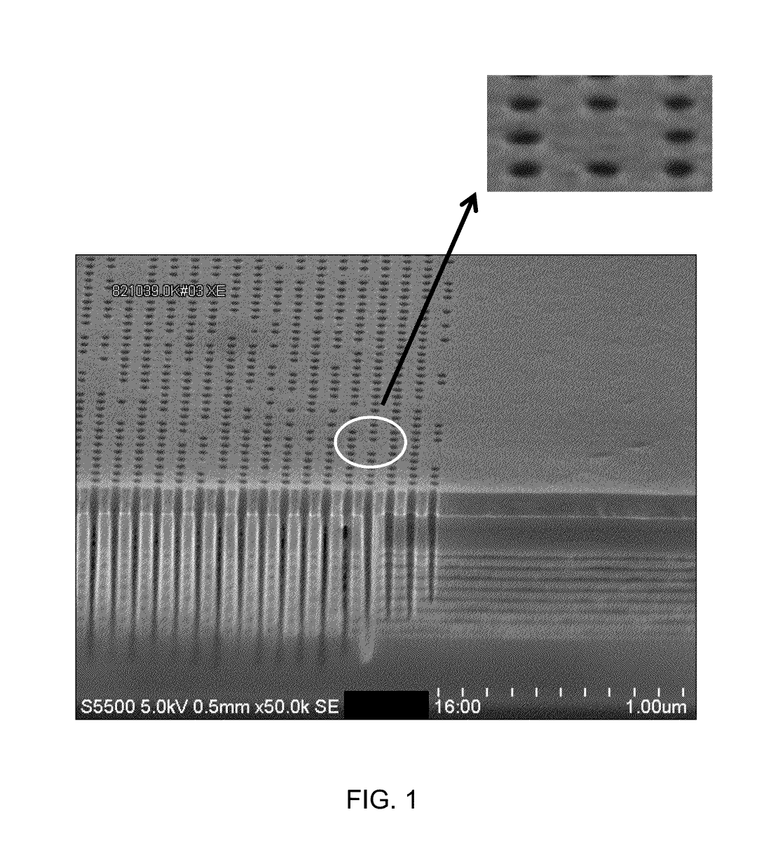

The specification for critical dimension uniformity (CDU) tightens as the technology shrinks down, and the mask CDU plays a more important role due to its more direct impact on the wafer CDU. Correct, suitable and sufficient mask critical dimension (CD) information may help find the root cause of the CDU error. Including feedback for the mask making process may allow for adjustment to improve the mask CDU in future versions. However, production masks have not previously provided enough and systematic mask CDU information for extracting the root cause of the mask error. For example, holes that are partially etched and do not extend completely through a layer, which may be referred to as blind holes, may present a serious issue at an after etch inspection (AEI) particularly for array boundary holes. FIG. 1 illustrates a blind hole problem in an edge region where holes are both partially etched and failed to etch at all.

The present disclosure provides a new methodology and mask design to address the above mentioned problems.

In general, a semiconductor device, such as a memory device, may be fabricated by forming a desired pattern or series of patterns on a mask, forming a photoresist layer on a substrate, and applying a photolithography process to the photoresist layer using the mask. More specifically, the mask having patterns thereon is aligned above the substrate having the photoresist layer formed thereon and subjected to an exposure to light, such as UV light, e-beams, x-rays, and/or other wavelength light and/or radiation. A pattern or series of patterns is formed on those portions of the photoresist layer exposed to the light, that is, those portions corresponding to the pattern(s) on the mask. In a positive tone development process, the patterns formed on the photoresist layer are subsequently etched to form the semiconductor device, whereas in a negative tone development process, the portions surrounding the patterns formed on the photoresist layer are etched to form the semiconductor device.

As mentioned before, the serious blind hole issue at the AEI check particularly for array boundary holes has become an even bigger problem in contemporary semiconductor manufacturing processes. Previously, process adjustments to improve device manufacturing yield were only made in the photo or etching steps. The inventors of the present disclosure discovered that the mask CD distribution trend may be similar to that of subsequent develop/etch CD trends. Therefore, in an embodiment, the causes of the problem are located in the early mask making stages in the manufacturing process to be solved as early as possible. The device production yield can be improved tremendously.

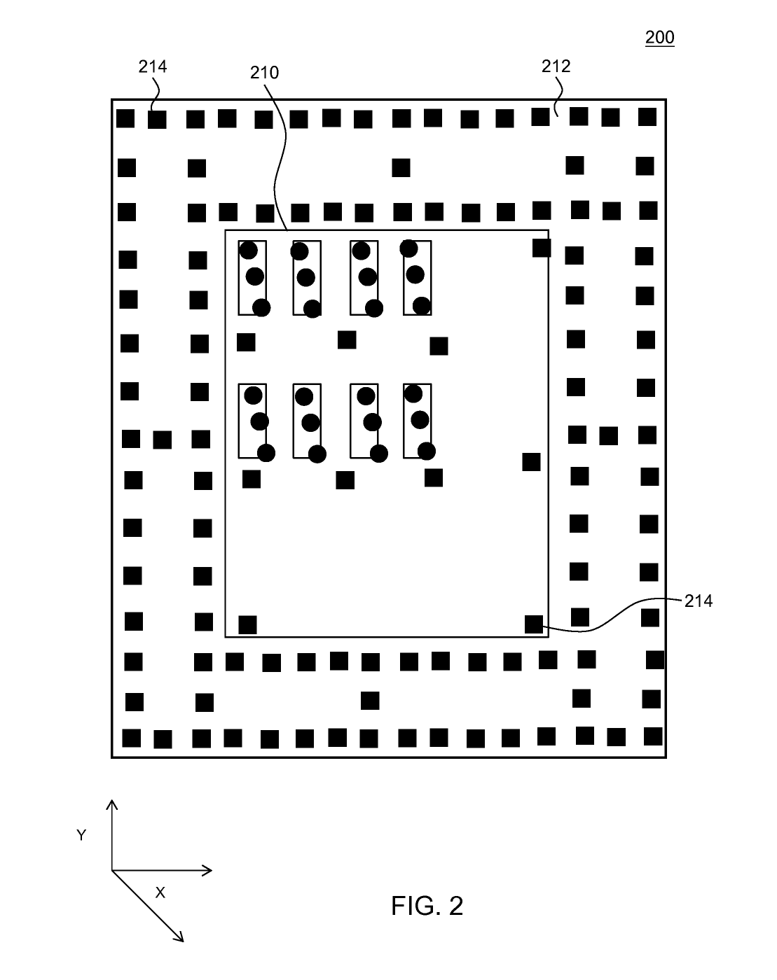

FIG. 2 illustrates a portion (e.g., one die) of an exemplary embodiment of a photomask 200 for use in fabricating a semiconductor device. The photomask 200 includes a cell region 210 near the middle and a monitor mark region 212 surrounding the cell region. In an embodiment, the cell region 210 is substantially rectangular in shape. In an embodiment, multiple monitor marks 214 may be uniformly distributed in the monitor mark region 212. Moreover, if the cell region 210 has enough space, additional monitor marks 214 can also be placed inside the cell region 210 to further enhance the CDU in the cell region 210 as well. The sample dimensions of one die of the photomask 200 may be 26 mm in length (X) and 32 mm in width (Y) while the cell region 210 may be 19.6 mm in length (X) and 24.7 mm in width (Y). Of course, these dimensions may varied based on the actual cell design.

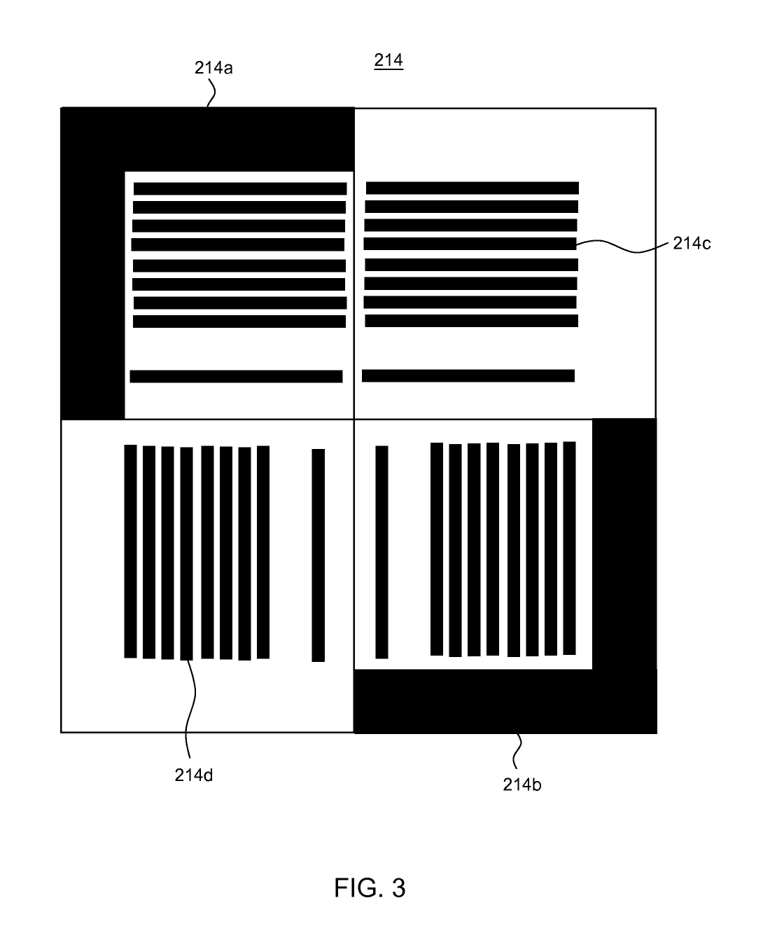

FIG. 3 illustrates an enlarged view of a monitor mark 214 in an example embodiment of the photomask 200 of FIG. 2 for use in fabricating a semiconductor device. The monitor mark 214 may include various types of patterns that check different effects that depends on many factors such as the design rule of the cell, the characteristics of the patterns in the main cell, and the behavior of the process tools used. For example, it may include a region 214a having horizontal lines with different line spacing inside a wide dark line for a line end performance check. It may also include a region 214b having vertical lines with different line spacing inside a wide dark line for a line end performance check. It may also include a region 214c having horizontal lines with different line spacing for a mask etch loading effect and/or mask proximity effect check. It may also include a region 214d having vertical lines with different line spacing for a X, Y bias check to see the variations of the exposure tool. Of course, it may be other combinations of patterns or fewer, such as one, patterns based on the different needs for the particular cell/mask design.

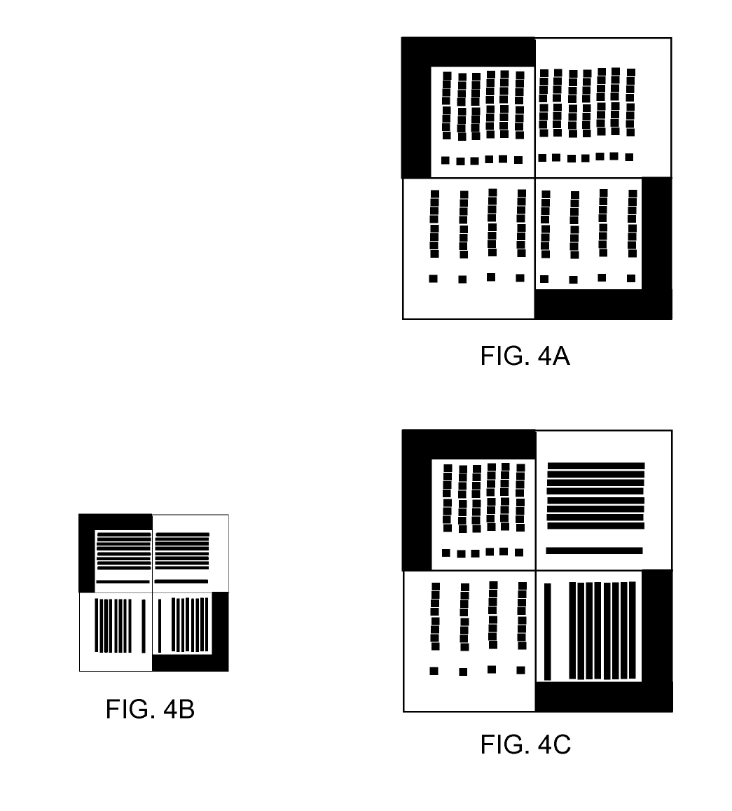

FIG. 4 show some examples of the other monitor mark patterns can be used as alternatives to the monitor mark 214 of FIG. 3. For example, dots may be used instead of or in addition to lines as shown in FIG. 4A. Or, a similar patter with a different cell size may be used as shown FIG. 4B. Or, a combination of line and dot patterns may be used as shown FIG. 4C.

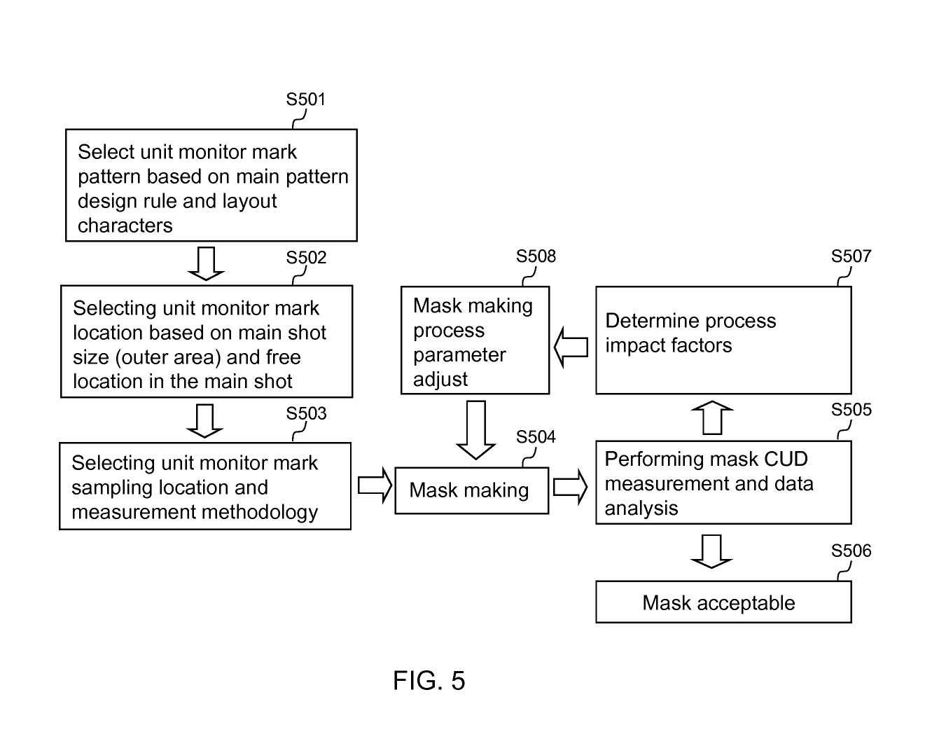

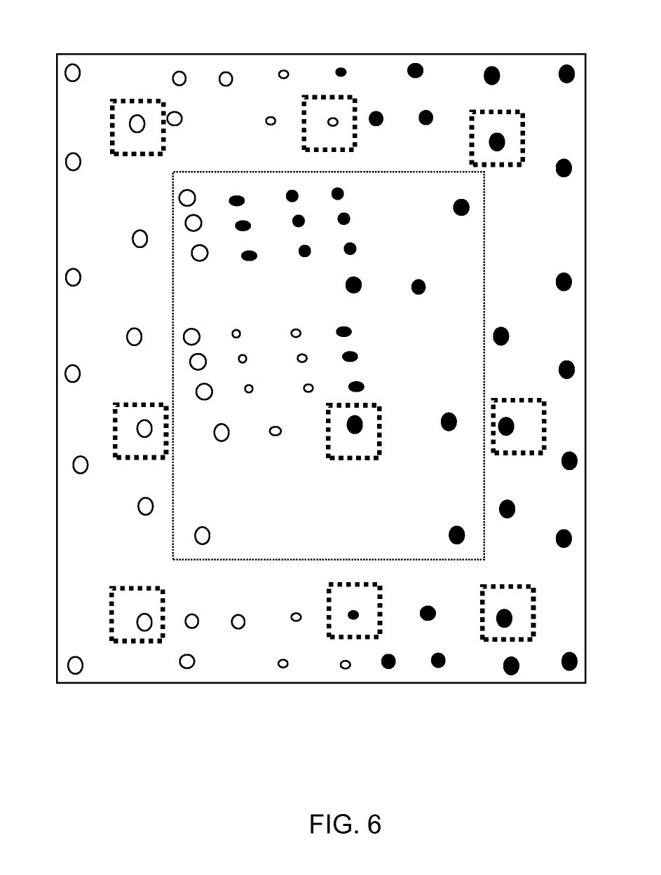

FIG. 5 is a flow chart illustrating a mask CDU monitoring process for making a photomask according to an embodiment. At step S501, a unit monitor mark pattern is selected based on a main cell pattern design rule and layout characters. For example, one or more of the patterns of FIGS. 3 and 4 may be selected. At step S502, a unit monitor mark location is selected based on main shot (cell) and free location within the main shot (cell). In an embodiment, the monitor mark locations may be selected both inside and outside cell area such as is shown in FIG. 2. At step S503, a unit monitor mark sampling location and measurement methodology is selected. In an embodiment, about ⅓ of the marks located both inside and outside the cell may be picked for sampling. Referring to FIG. 6, selected unit monitor marks are shown inside dashed lines. These marks may be selected in symmetric locations for better understanding of geometry effects. Although more information may be collected with larger sample numbers, larger numbers will increase time and precision needed.

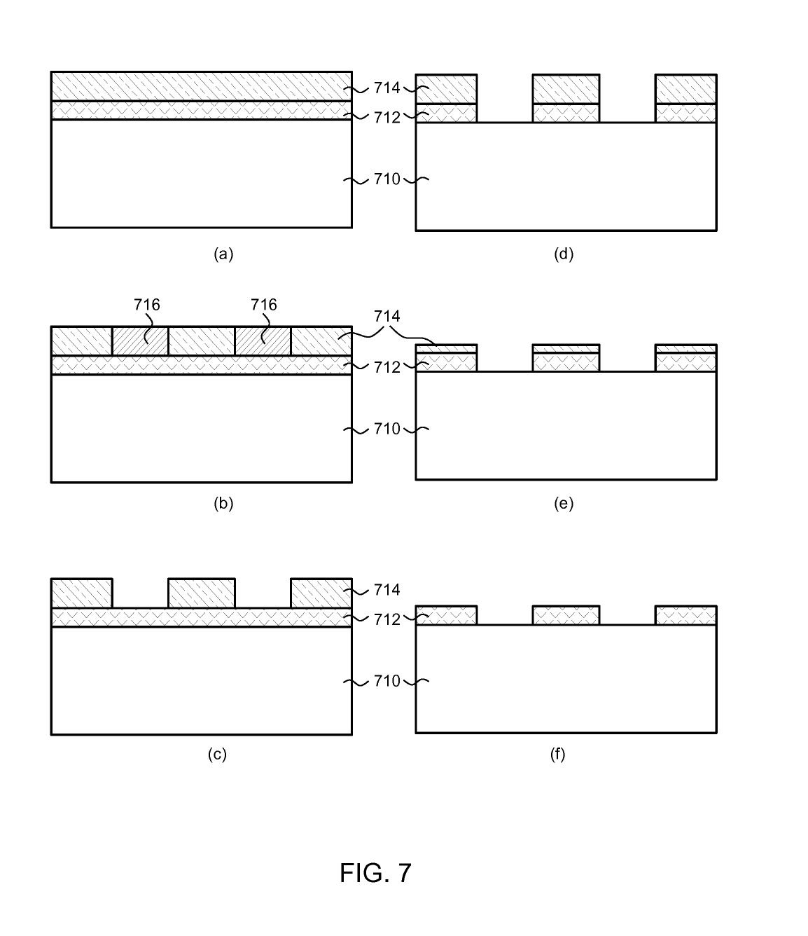

At step S504, the mask making and feedback loop may be started. In an embodiment, the mask may be a binary image mask (BIM) fabricated by a process such as that shown in FIG. 7. Referring to FIG. 7A, the BIM mask making process may begin with a Cr layer 712 and photoresist layer 714 deposited on a substrate 710, which may be glass. Referring to FIG. 7B, the photoresist layer 714 may be exposed to light such as UV light to form a pattern of exposed photoresist portions 716 in the photo resist layer 714. Referring to FIG. 7C, the photoresist may be developed to remove the exposed photoresist portions 716. The remaining photoresist layer 714 may be baked. Referring to FIG. 7D, the portions of the Cr layer 712 not protected by the patterned photoresist layer 714 may be etched. Referring to FIG. 7E, the remaining photoresist layer 712 may be stripped to be partially or completely removed. Referring to FIG. 7F, the substrate 710 may be cleaned to provide a mask ready for inspection.

During the mask fabrication process, CDU variation within a mask may be reduced by precisely controlling a number of parameters. Examples of such parameters include Cr film thickness, resist coating uniformity, E-beam tool control stability, resist baking hot plate temperature uniformity and etch loading effect . . . . Referring back to FIG. 5, at step S505, mask CDU may be measured and analyzed. FIG. 6 illustrates an exemplary measurement result. In the example of FIG. 6, dark circles indicate holes that are 5 nm or more over the specification target value and light circles indicate holes that are 5 nm or more below the specification target value. The measurement result may collect data to monitor several kinds of mask effects (e.g., defects). In this example, the area in the right hand side of the mask shows a trend of +5 nm holes. Referring back to FIG. 5, if the measured mask CDU is within a predetermined specification, then the mask is ready to use in manufacturing and the process stops at step S506; otherwise, process impact factors are determined at step S507. For example, if the mask CDU problem is determined to be caused by uneven heat application (for example by a hot plate used for baking) or Cr film thickness, then the mask making process parameters (e.g., heat application or Cr film thickness) are adjusted accordingly at step S508. Then, the mask making process returns to step S504 to make the mask again. This may be repeated until the measured mask CDU is within the predetermined specification. As one can see from FIG. 6, the monitor marks of the present disclosure are particularly useful to identify factors affecting the mask at different locations during the mask making process.

In an alternative embodiment, the monitor mark 214 can be other types of patterns different from the ones shown in FIGS. 3 and 4. For example, the monitor mark may include, horizontal dots with different spacing inside wide dark lines for a line end performance check. It can also include vertical dots with different spacing inside wide dark lines for a line end performance check. It can also include horizontal dots with different spacing for a mask etch loading effect and/or mask proximity effect check. It can also include vertical dots with different spacing for an X, Y bias check. Of course, it can also include other combination of dots and lines or just one pattern based on the different needs for the particular cell/mask design. Also, the exemplary embodiment in FIG. 7 is a process flow for the BIM type mask process but other types of mask such as phase shift mask may also be used and are within the scope of the present disclosure.

In fabricating a semiconductor device, when a photoresist layer of a substrate is subjected to an exposure process, such as by applying light (UV light, e-beam, x-rays, etc.), the photomask may form monitor mark patterns on the photoresist layer that resemble the monitor mark patterns on the photomask. It is recognized herein that the monitor mark patterns formed on the photoresist layer will enable the semiconductor device to achieve, among other things, reduced corner rounding effects, increased DoF, increased CDU, increased contact area on bottom layer, and reduced probability of blind patterns (or blind holes).

While various embodiments in accordance with the disclosed principles have been described above, it should be understood that they have been presented by way of example only, and are not limiting. Thus, the breadth and scope of the example embodiments described herein should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A method of monitoring mask uniformity, comprising:
selecting a unit monitor mark pattern;
selecting unit monitor mark locations based on a main cell size;
determining a unit monitor mark sampling location and measurement methodology;
starting a mask making process;
measuring mask critical dimension uniformity (CDU) and analyzing data;
identifying a process impact factor if the mask CDU is not within a predetermined specification, adjusting a mask making process parameter based on the identified process impact factor, and repeating the mask making process, measuring, identifying and adjusting steps until the mask CDU is within the predetermined specification.

2. The method of monitoring mask uniformity of claim 1, wherein the unit monitor mark locations are disposed outside a cell area.

3. The method of monitoring mask uniformity of claim 2, wherein the unit monitor mark locations are disposed inside the cell area.

4. The method of monitoring mask uniformity of claim 1, wherein the unit monitor mark includes lines, dots and combinations of lines and dots.

5. The method of monitoring mask uniformity of claim 1, wherein the unit monitor mark includes at least two different types of patterns.

6. The method of monitoring mask uniformity of claim 1, wherein the process impact factor includes one or more of: a mask film thickness, a resist coating uniformity, an E-beam tool control stability, a resist baking hot plate temperature uniformity, and an etch loading effect.

7. A photomask for use in fabricating a semiconductor device, the photomask comprising:
a cell pattern; and
a plurality of monitor marks surrounding the cell pattern.

8. The photomask of claim 7, further comprising a plurality of monitor marks inside the cell pattern.

9. The photomask of claim 7, wherein the monitor mark includes lines, dots and combinations of lines and dots.

10. The photomask of claim 7, wherein the monitor mark includes at least two different types of patterns.

11. The photomask of claim 7, wherein the cell pattern is rectangular.
